(19) United States
(12) Patent Application Publication
(10) Pub. No.: US 2026/0156793 A1
(43) Pub. Date: Jun. 4, 2026

(54) ELECTRONIC DEVICE

(71) Applicant: Panasonic Automotive Systems Co., Ltd., Kanagawa (JP)

(72) Inventor: Masatoshi NAKABO, Osaka (JP)

(73) Assignee: Panasonic Automotive Systems Co., Ltd., Kanagawa (JP)

(21) Appl. No.: 19/412,160

(22) Filed: Dec. 8, 2025

Related U.S. Application Data
(63) Continuation of application No. PCT/JP2024/021897, filed on Jun. 17, 2024.

(30) Foreign Application Priority Data
Aug. 9, 2023 (JP) 2023-130094

(51) Int. Cl. H05K 9/00

(52) U.S. Cl. CPC H05K 9/0009; H05K 9/0084

(57) ABSTRACT

An electronic device includes: a housing; a board that is disposed inside the housing and on which a plurality of circuit elements are mounted; and a shield case that is provided on the board and is made of metal. Among the plurality of circuit elements, a circuit element requiring electromagnetic shielding is placed in a region of the board where the shield case is provided.

### CROSS REFERENCE TO RELATED APPLICATIONS

This is a continuation application of PCT International Application No. PCT/JP2024/021897 filed on Jun. 17, 2024, designating the United States of America, which is based on and claims priority of Japanese Patent Application No. 2023-130094 filed on Aug. 9, 2023. The entire disclosures of the above-identified applications, including the specifications, drawings, and claims are incorporated herein by reference in their entirety.

### FIELD

The present disclosure relates to an electronic device.

### BACKGROUND

Patent Literature (PTL) 1 discloses a technique of attaching a shield case to a circuit board built into an electronic device.

### CITATION LIST

### Patent Literature

Japanese Unexamined Patent Application Publication No. 2005-159144

### SUMMARY

However, the method in aforementioned PTL 1 can be improved upon.

In view of this, the present disclosure provides an electronic device capable of improving upon the related art.

An electronic device according to an aspect of the present disclosure includes: a housing; a board that is disposed inside the housing and on which a plurality of circuit elements are mounted; and a shield case that is provided on the board and is made of metal. Among the plurality of circuit elements, a circuit element requiring electromagnetic shielding is placed in a region of the board where the shield case is provided.

A wiring board according to an aspect of the present disclosure is capable of improving upon the related art.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a perspective view illustrating a configuration example of an electronic device according to an embodiment.

FIG. 2 is a perspective view illustrating a configuration example of a shield case according to an embodiment.

FIG. 3 is a diagram illustrating an example of a wiring pattern that does not use a meander pattern according to the embodiment.

FIG. 4 is a diagram illustrating an example of a wiring pattern that does not use the meander pattern according to the embodiment.

FIG. 5 is a diagram illustrating an example of a wiring pattern using the meander pattern according to the embodiment.

FIG. 6 is a diagram illustrating an example of a wiring pattern using the meander pattern according to the embodiment.

FIG. 7 is a diagram illustrating a configuration example of a microstrip line of a surface layer according to the embodiment.

FIG. 8 is a diagram illustrating a configuration example of a stripline of an inner layer according to the embodiment.

### DESCRIPTION OF EMBODIMENTS

Hereinafter, embodiments will be specifically described with reference to the Drawings. Furthermore, each of the embodiments described below shows a generic or specific example. The numerical values, shapes, materials, structural elements, the arrangement and connection of the structural elements, steps, the processing order of the steps, etc., shown in the following exemplary embodiments are mere examples, and are therefore not intended to limit the present disclosure. Furthermore, among the elements in the following embodiments, structural elements not recited in the independent claims are described as optional elements.

Furthermore, the respective figures are schematic diagrams and are not necessarily precise illustrations. It should be noted that in the respective figures, elements that are substantially the same are given the same reference signs, and overlapping description may be omitted or simplified.

### Embodiment

### [Underlying Knowledge Forming Basis of the Invention]

With in-vehicle devices, the advancement of digitalization of electronic devices due to the shift to electric vehicles (EVs) has led to an increase in noise interference between devices. Furthermore, with the increase in the number of devices that are provided in vehicles, there is a demand for in-vehicle devices to be lightweight. As a method for realizing weight reduction, a method of using a resin housing instead of a metal housing has been considered. However, there is a concern that using a resin housing will reduce noise resistance. Due to these causes, measures for electromagnetic compatibility (EMC) in in-vehicle devices have become an issue.

In the present embodiment, instead of enclosing the entire board in a metal housing, devices that require noise countermeasures are grouped together and placed in a specific area, and a shield case that encloses the specific area is used. In this manner, by implementing partial shielding, weight reduction can be realized while realizing noise suppression. Furthermore, even when a partial shielding structure is used, EMI (Electromagnetic Interference) standards can be met.

Furthermore, when using a shield case, the placement intervals and impedance of joints that join the shield case and the ground plane of the board are important in order to enhance the effect of the shield case. As a common method, there is a method that provides a plurality of joints at intervals that are less than or equal to 1/20 of the noise frequency wavelength. Alternatively, it is possible to connect the entire periphery of the shield case to the ground plane of the board. When connecting the entire periphery, while it is possible to reduce impedance, it becomes impossible to form a wiring pattern on the surface layer at the joints. This makes it difficult to draw out wiring from the inside of the shield case to the outside. In this manner, when connecting the entire periphery, there is the issue that constraints on the wiring pattern arise.

In the present embodiment, the intervals of these joints are appropriately set within a range that can achieve a noise suppression effect, thereby reducing constraints on the wiring pattern while suppressing noise.

Furthermore, the external size of the board is also determined by the product size that can be placed inside the vehicle cabin. Furthermore, due to the constraints on the external shape of the board, the distance between each component (i.e., the wiring pattern length) cannot be freely determined in the layout of each component. This causes the wiring length of the wiring in the board to match the specific wiring length corresponding to a specific frequency band (hereinafter also referred to as specific band), such as the Beidou Navigation Satellite System (BDS) band and the Global Navigation Satellite System (GLONASS) band which have the strictest limit values in the EMC standard, resulting in a problem of high noise levels in the specific band. Here, the specific wiring length is a wiring length that causes wiring to function as an antenna pattern for the specific band.

In contrast, in the present embodiment, the wiring length of all wiring within the board is intentionally made long so that it does not become a specific wiring length. This makes it possible to prevent the wiring from becoming an antenna pattern for a specific band. Therefore, for example, the EMI standard can be met even when a resin housing is used.

In addition, in the present embodiment, not only is the wiring length controlled, but the actual effective relative dielectric constant is calculated from a relative dielectric constant based on the board material. Moreover, propagation delay characteristics of digital signals in high-speed transmission paths in surface layer wiring and inner layer wiring are taken into account. With this, the wiring length for each layer in the board can be precisely controlled.

### [Configuration of Electronic Device]

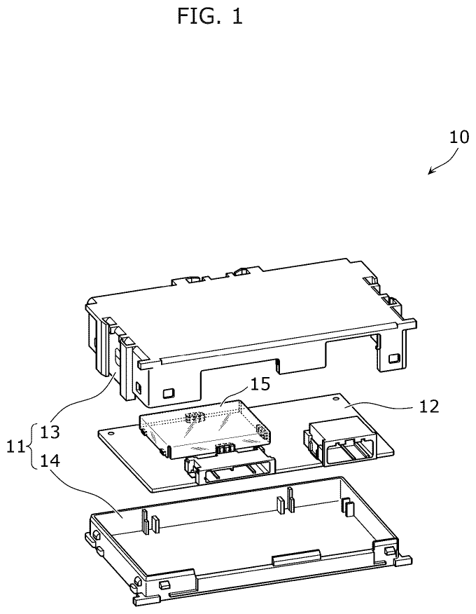

First, a configuration example of electronic device 10 according to the present embodiment will be described. FIG. 1 is a perspective view of electronic device 10 according to the present embodiment. FIG. 1 illustrates electronic device 10 in an exploded state.

Electronic device 10 includes housing 11, board 12, and shield case 15. Housing 11 is, for example, made of resin, and includes upper chassis 13 and lower chassis 14.

Board 12 is a wiring board, and includes a plurality of wiring layers. These wiring layers include a surface layer and one or more inner layers. It should be noted that, although the number of wiring layers is not particularly limited, board 12 is a 4-layer board or a 6-layer board, for example. Board 12 is disposed inside housing 11.

Furthermore, a plurality of elements (electronic components) such as integrated circuits are disposed on board 12. It should be noted that only some of these elements are illustrated in FIG. 1, with the rest being omitted.

Electronic device 10 is, for example, an Electronic Control Unit (ECU) for in-vehicle use. The ECU includes, for example, at least one of an Active Sound Control (ASC) unit or an Active Noise Control (ANC) unit that perform in-vehicle sound-related processing. In other words, the ECU has the function of at least one ASC or ANC. The ASC unit performs processing to add engine sounds, and so on, in an EV or hybrid vehicle. The ANC unit performs processing to cancel noise inside the vehicle.

For example, electronic device 10 includes a power supply circuit such as a DC-DC converter, a processor such as a microcomputer or a digital signal processor (DSP), a memory such as a flash memory, and a communication circuit.

It should be noted that electronic device 10 is not limited to the above example. Electronic device 10 may be an electronic device for in-vehicle use other than the above, or may be an electronic device other than for in-vehicle use.

[Configuration of Shield case]

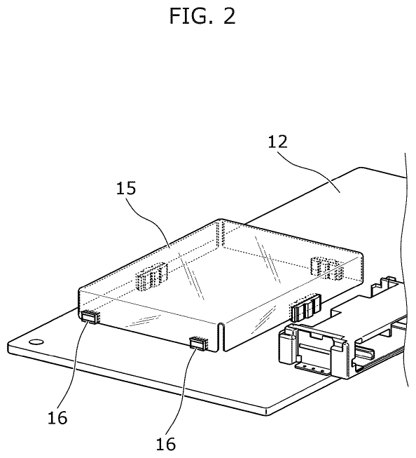

FIG. 2 is a perspective view illustrating the configuration of shield case 15. Shield case 15 is disposed to enclose a specific area of board 12. Shield case 15 is made of metal, and is made of steel plate cold commercial (SPCC), for example.

Among the plurality of circuit elements provided to board 12, circuit elements that require electromagnetic shielding are placed in the specific area enclosed by shield case 15. Furthermore, the rest of the circuit elements are placed outside the specific area and are not enclosed by shield case 15. For example, circuit elements that require electromagnetic shielding include the power supply circuit and an overload protection circuit. Furthermore, circuit elements that are placed outside the specific area (i.e., outside shield case 15) include the communication circuit.

Furthermore, as illustrated in FIG. 2, a plurality of shield clips 16 are used as a method for connecting shield case 15 and board 12. The plurality of shield clips 16 are surface mounted on board 12. By sandwiching shield case 15 between the plurality of shield clips 16, shield case 15 is fixed to board 12 and is electrically connected to the ground plane of board 12.

### [Adjustment of Wiring Length]

In the present embodiment, the wiring length of all the wiring of board 12 is made long so as not to become a specific wiring length corresponding to a specific band. This makes it possible to prevent the wiring from becoming an antenna pattern in a specific band. Specifically, board 12 does not include wiring having the specific wiring length corresponding to the specific band. In other words, the wiring length of all the wiring of board 12 is not the specific wiring length.

Specifically, a meander pattern (also called a meander-type pattern) is used as a method for adjusting the wiring length of board 12. A meander pattern is not a wiring pattern in which the wiring length is shortest, but a wiring pattern in which the wiring length is lengthened by making the wiring meander.

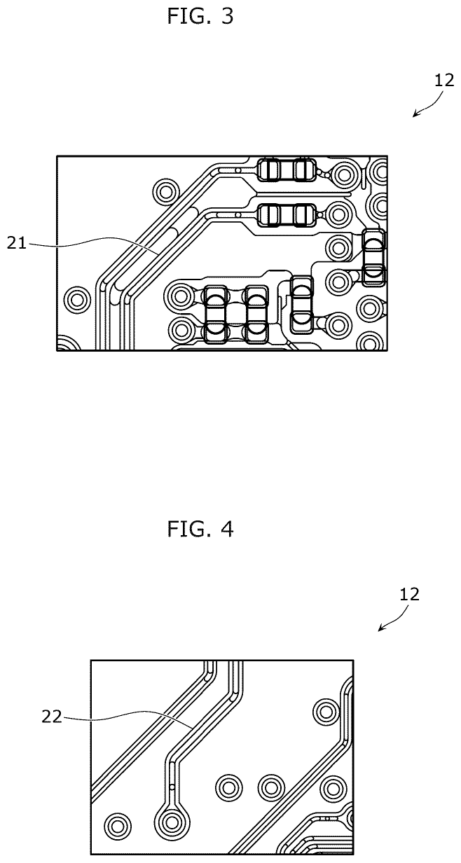

FIG. 3 and FIG. 4 are diagrams for comparison, and illustrate examples of wiring patterns that do not use meander patterns. FIG. 3 and FIG. 4 respectively illustrate wiring 21 and wiring 22 that do not use meander patterns.

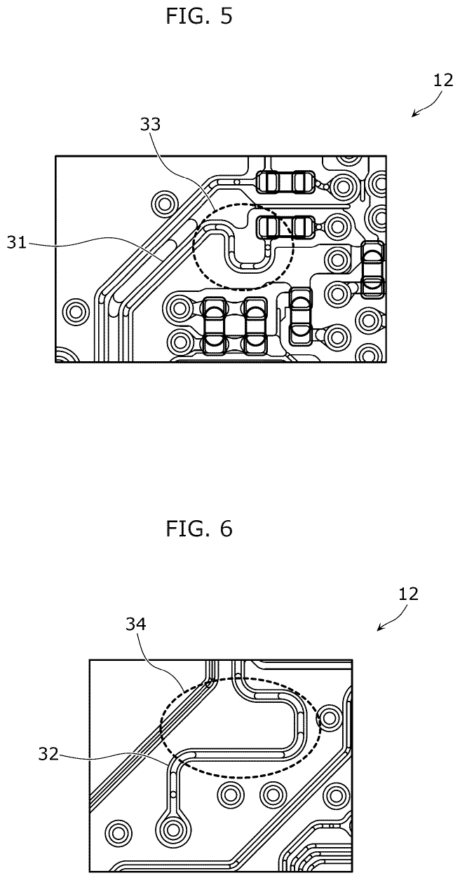

FIG. 5 and FIG. 6 correspond to FIG. 3 and FIG. 4, respectively, and are diagrams illustrating examples of wiring patterns using meander patterns. Wiring 31 illustrated in FIG. 5 includes meander pattern 33. Wiring 32 illustrated in FIG. 6 includes meander pattern 34.

Here, the meander patterns is generally used to make the wiring lengths of multiple wirings uniform to align the delay times of signals on multiple wirings, for example, data lines and clock lines, in order to make communication timings coincide, that is, to make propagation delay characteristics match. In other words, the meander pattern is used to carry out equal-length wiring for respective signal lines that must be synchronized. In contrast, in the present embodiment, the meander pattern is used to prevent the wiring length from becoming a specific wiring length.

### [Calculation of Specific Wiring Length]

Next, a method for calculating the specific wire length will be described. First, the propagation velocity of a wiring in a vacuum will be described. The propagation velocity in a vacuum is 300,000 km/sec, which is the same as the speed of light c. Specifically, the propagation velocity in a vacuum is defined by (Equation 1) below.

$$c = 1 / √ ( ε0 \times μ0 ) \qquad ( Equation 1 )$$

Here, ε0 is the dielectric constant of a vacuum, and ε0=8.85×10⁻¹². μ0 is the magnetic permeability of a vacuum, and μ0=4π×10⁻⁷. Therefore, the propagation velocity c=2.99792458×10⁸ [m/sec].

On the other hand, in the case of coaxial cables, the propagation velocity decreases mainly due to the influence of the relative dielectric constant εr of the material. This decrease in propagation velocity is called wavelength reduction. The wavelength in this case is represented by (Equation 2) below.

$$λ = λ 0 \times 1 / √ ε r \qquad ( Equation 2 )$$

Here, λ0 is the wavelength in a vacuum. For example, when the insulator is polyethylene, εr=2.2 to 2.4, and the propagation velocity is calculated as 2.99792458/√2.3=1.97677293×10⁸ [m/sec]. In other words, the propagation velocity in a coaxial cable is approximately 66% of that in a vacuum. Therefore, the wavelength reduction rate is 0.66.

As with coaxial cables, the propagation velocity of a signal in wiring formed on the board can be calculated.

Here, this propagation velocity is generally calculated to be approximately half the speed of light c. If the board material is glass epoxy (FR-4), its relative dielectric constant is 4.3/1 GHz. Therefore, the propagation velocity is 2.99792458/√4.3=1.4457276101×10⁸ [m/sec].

However, the propagation velocity obtained through this calculation includes an error compared to the actual propagation velocity. In particular, since there is a large error in the GHz band, stricter control is required.

Here, microstrip lines are used on the surface layer of the board, and striplines are used on the inner layer of the board. In the present embodiment, different propagation velocities are precisely calculated for the surface layer and the inner layer by performing different calculations for the surface layer and the inner layer.

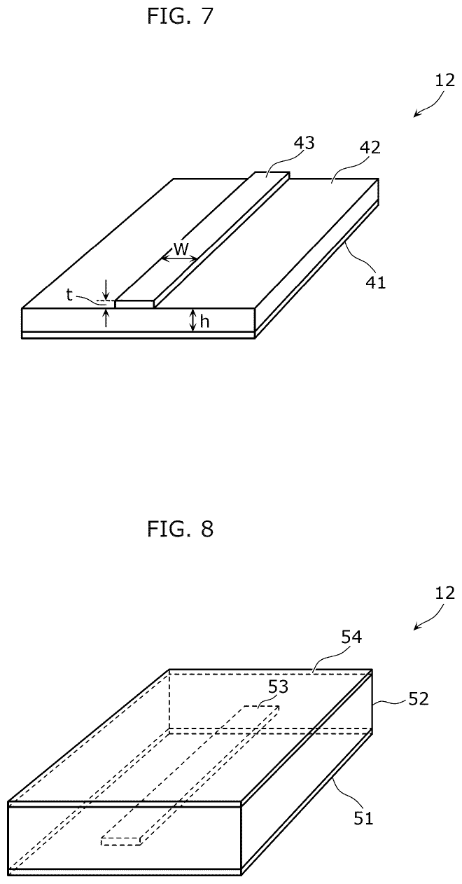

FIG. 7 is a diagram illustrating a configuration example of a microstrip line of the surface layer. As illustrated in FIG. 7, in the surface layer, board 12 includes ground conductor 41, insulating layer 42, and wiring 43. Ground conductor 41 is an electrically grounded conductor, and is, for example, a metal layer. Insulating layer 42 is an insulator layer disposed between ground conductor 41 and wiring 43, and is also called an insulator prepreg. Wiring 43 is a metal wiring pattern, and transmits a signal.

In the present embodiment, the effective relative dielectric constant εe is calculated from (Equation 3) below using the relative dielectric constant εr of insulating layer 42, the thickness (height) h of insulating layer 42, and the width w of wiring 43.

$$ε e = ( ( ε r + 1 ) / 2 ) + ( ( ε r - 1 ) / 2 ) \times 1 / ( √ ( 1 + ( 10 \times h ) / w ) \qquad ( Equation 3 )$$

Furthermore, the propagation velocity v is calculated from (Equation 4) below using the speed of light c and the effective relative dielectric constant εe of insulating layer 42.

$$v = c / √ ε e \qquad ( Equation 4 )$$

In addition, the wavelength λ is calculated from the frequency f of the specific band and the propagation velocity v, using (Equation 5) below.

$$λ = v / f \qquad ( Equation 5 )$$

FIG. 8 is a diagram illustrating a configuration example of a stripline of an inner layer. As illustrated in FIG. 8, in the inner layer, board 12 includes ground conductors 51 and 54, insulating layer 52, and wiring 53. Ground conductors 51 and 54 are electrically grounded conductors, and are, for example, metal layers. Insulating layer 52 is an insulator layer disposed between ground conductor 51 and ground conductor 54. Wiring 53 is a metal wiring pattern disposed inside insulating layer 52, and transmits a signal.

Furthermore, the propagation velocity v is calculated from (Equation 6) below using the speed of light c and the relative dielectric constant εr of insulating layer 42.

$$v = c / √ ε r \qquad ( Equation 6 )$$

Furthermore, the wavelength λ is calculated from the propagation velocity v obtained from (Equation 6), using (Equation 5) above. In this manner, different propagation velocities v are calculated and different wavelengths λ are calculated, for the surface layer and the inner layer.

Next, the specific wiring length for the surface layer is calculated based on the wavelength λ of the surface layer, and the specific wiring length for the inner layer is calculated based on the wavelength λ of the inner layer. For example, the specific wiring length is λ/4.

Next, all wiring patterns for the surface layer and the inner layer are created so that the wiring length of the wiring in the surface layer is not the calculated specific wiring length for the surface layer, and so that the wiring length of the wiring in the inner layer is not the calculated specific wiring length for the inner layer. For example, the wiring patterns are created based on a predetermined rule (for example, so that the wiring length is the shortest). Next, from the created wiring patterns, wiring having a wiring length that matches the calculated specific wiring length is extracted, and the extracted wiring is replaced with wiring having a different wiring length (for example, wiring having the meander pattern described above).

For example, when εr=3.9, h=0.2 mm, and w=0.1 mm, the propagation velocity v of the surface layer is 1.80481941×10⁸ [m/sec], and the propagation velocity v of the inner layer is 1.51805812×10⁸ [m/sec]. Therefore, the specific wiring length for the surface layer corresponding to the BDS band (1.56 GHz) is approximately 28.9 mm, and the specific wiring length for the inner layer is approximately 24.3 mm. Specifically, since the BDS band is a band from 1559.052 MHz to 1563.144 MHz, the specific wiring length for the surface layer corresponding to the BDS band is included in the range of 28.8 mm to 29.0 mm, and the specific wiring length for the inner layer is included in the range of 24.2 mm to 24.4 mm.

Furthermore, the specific wiring length for the surface layer corresponding to the GLONASS band (1.60 GHz) is approximately 28.1 mm to 28.2 mm, and the specific wiring length for the inner layer is approximately 23.7 mm to 23.8 mm. Specifically, since the GLONASS band is a band from 1594.0625 MHz to 1609.375 MHz, the specific wiring length for the surface layer is included in the range of 28.0 mm to 28.4 mm, and the specific wiring length for the inner layer is included in the range of 23.5 mm to 23.9 mm.

It should be noted that, although an example in which the specific wiring length is λ/4 has been described above, the specific wiring length may be λ/2. In that case, the specific wiring length for the surface layer corresponding to the GLONASS band (1.60 GHz) is approximately 56.2 mm to 56.4 mm, and the specific wiring length for the inner layer is approximately 47.4 to 47.6 mm. Specifically, since the GLONASS band is a band from 1594.0625 MHz to 1609.375 MHz, the specific wiring length for the surface layer is included in the range of 56.0 mm to 56.8 mm, and the specific wiring length for the inner layer is included in the range of 47.0 mm to 47.8 mm. In addition, both λ/4 and λ/2 may be used as the specific wiring length.

When λ/2 is used, in the above example, the specific wiring length for the surface layer corresponding to the BDS band (1.56 GHz) is approximately 57.8 mm, and the specific wiring length for the inner layer is approximately 48.6 mm. For example, the specific wiring length for the surface layer corresponding to the BDS band is included in the range of 57.6 mm to 58.0 mm, and the specific wiring length for the inner layer is included in the range of 48.4 mm to 48.8 mm.

Furthermore, the specific wiring length for the surface layer corresponding to the GLONASS band (1.60 GHz) is approximately 56.3 mm to 56.5 mm, and the specific wiring length for the inner layer is approximately 47.3 mm to 47.5 mm. For example, the specific wiring length for the surface layer is included in the range of 56.0 mm to 56.8 mm, and the specific wiring length for the inner layer is included in the range of 47.0 mm to 47.8 mm.

It should be noted that the numerical ranges given above are just examples. If the part number of the board is different, the dielectric constant εr will change due to the different base material, and thus control of the wiring length is required. Furthermore, to ensure a greater margin, the numerical range of the specific wiring lengths described above may be widened. Conversely, to widen the range of usable wiring lengths, the numerical range of the specific wiring lengths described above may be narrowed.

It should be noted that, although the BDS band and the GLONASS band are given as examples of the specific band in the foregoing description, the specific band may be another frequency band. Furthermore, the specific band is not limited to the GHz band. For example, the specific band may be the operating frequency of a circuit or the like included in electronic device 10, or the operating frequency of a device connected to electronic device 10. Furthermore, the specific band may be a frequency that is n times (n is a natural number) these operating frequencies. For example, the specific band may be a frequency that is an odd multiple of these operating frequencies.

For example, the specific band may be the frequency of a signal transmitted from the DC-DC converter. For example, when the frequency is 2.10 GHz and λ/2 is used, the specific wiring length for the surface layer is approximately 43.0 mm, and the specific wiring length for the inner layer is approximately 36.1 mm.

Furthermore, there may be a plurality of specific bands. In this case, the unused wiring length is determined for each specific band, and the wiring pattern is generated so as not to include wiring having any of the determined wiring lengths.

### Adjustment of Shield Clip Interval

The noise suppression effect of shield case 15 is dependent on the intervals of shield clips 16. Specifically, in places where shielding clips 16 are not arranged, a gap of about several mm is created between shield case 15 and board 12. Noise propagates through this gap.

Furthermore, the noise suppression effect can be enhanced by narrowing the intervals between shield clips 16, but increasing the number of shield clips 16 to be placed increases the constraints on the wiring pattern to be placed on the surface. In the present embodiment, the intervals of shield clips 16 are appropriately set within a range that can achieve a noise suppression effect, thereby reducing constraints on the wiring pattern while suppressing noise.

Specifically, the wavelength λ is calculated from the frequency f of the specific band and the propagation velocity v in a vacuum, using (Equation 5) above. Next, the specific interval for shield clips 16 is calculated based on wavelength λ. For example, the specific interval is λ/2. It should be noted that the specific interval may be λ/4.

Next, the intervals for shield clips 16 are determined so that they are not the specific interval. For example, the intervals for shield clips 16 are determined so as to be narrower than the specific interval.

For example, the specific interval corresponding to the BDS band (1.56 GHz) is 96.1 mm, the specific interval corresponding to the GLONASS band (1.60 GHz) is 93.7 mm, and the specific interval corresponding to the frequency (2.10 GHz) of the signal emitted from the DC-DC converter is 71.4 mm.

It should be noted that, by widening the intervals of shield clips 16, the constraints on the surface layer wiring can be further reduced. Therefore, for example, by making the intervals of shield clips 16 wider than 1/20 of the wavelength of a commonly used noise frequency (e.g., 9.4 mm for 1.6 GHz), the constraints on the surface layer wiring can be reduced more than when intervals of less than or equal to 1/20 of the wavelength are used. In other words, the intervals of shield clips 16 may be narrower than the specific interval and wider than 1/20 of the wavelength.

It should be noted that, although there are a plurality of intervals between adjacent shield clips 16, all of the intervals need not be the same. In this case, the all of the plurality of intervals are narrower than the specific interval. On the other hand, all of the intervals need not be wider than 1/20 of the wavelength, and it is sufficient that at least one of the intervals is wider than 1/20 of the wavelength. Even in this case, the constraints on the surface wiring can be reduced more than when intervals of less than or equal to 1/20 of the wavelength are used.

### Advantageous Effects, Etc.

Inventions derived from the disclosure of the present Description are, for example, the inventions described below. Hereinafter, the inventions derived from the disclosure of the present Description will be described together with the advantageous effects and the like obtained through the inventions.

For example, electronic device 10 according to an aspect of the present disclosure includes: housing 11; board 12 that is disposed inside housing 11 and on which a plurality of circuit elements are mounted; shield case 15 that is provided on the board and is made of metal. Among the plurality of circuit elements, a circuit element requiring electromagnetic shielding is placed in a region of board 12 where shield 15 case is provided.

Accordingly, weight reduction can be realized compared to when the entire board is enclosed by a metal housing. Furthermore, noise suppression can be realized for the circuit element requiring electromagnetic shielding. Therefore, weight reduction and noise suppression can be realized.

For example, electronic device 10 further includes: a plurality of shield clips 16 that electrically connect shield case 15 to a ground pattern of board 12. Intervals of the plurality of shield clips 16 are set based on a propagation characteristic of a noise in vacuum. For example, the propagation characteristic is the propagation velocity or the wavelength.

Accordingly, the intervals of shield clips 16 can be set considering an interval having the effect of reducing noise in the specific band. Therefore, by widening the intervals while suppressing a reduction in the noise suppression effect, constraints on the surface layer wiring can be reduced.

For example, the intervals of the plurality of shield clips may be smaller than a specific interval based on the propagation characteristic of the noise in a vacuum and greater than 1/20 of a wavelength of the noise.

Accordingly, the constraints on the surface layer wiring can be reduced more than when intervals of less than or equal to 1/20 of the wavelength are used, while suppressing a reduction in the noise suppression effect.

For example, the specific interval may be determined based on a wavelength λ determined based on λ=v/f, where: f is a frequency of the noise; and v is a propagation velocity in a vacuum, and the specific interval may be λ/2 or λ/4.

Therefore, the constraints on the surface layer wiring can be reduced while appropriately suppressing a reduction in the noise suppression effect.

For example, when the frequency of the noise is 2.10 GHz, the specific interval may be 71.4 mm; when the frequency of the noise is 1.60 GHz, the specific interval may be 93.7 mm; and when the frequency of the noise is 1.56 GHz, the specific interval may be 96.1 mm.

Therefore, the constraints on the surface layer wiring can be reduced while appropriately suppressing a reduction in the noise suppression effect.

For example, the circuit element requiring the electromagnetic shielding may include a power supply circuit and an overload protection circuit. Accordingly, the noise of the circuit element requiring the electromagnetic shielding can be reduced.

For example, the housing may be made of resin. Accordingly, weight reduction of electronic device 10 can be realized.

For example, board 12 includes a plurality of wiring layers. At least a portion of wiring 31 (or wiring 32) disposed in the plurality of wiring layers includes meander pattern 33 (or meander pattern 34). The meander pattern is set based on different parameters for wiring disposed in different wiring layers among the plurality of wiring layers. Here, the parameters are, for example, the propagation velocity v, the wavelength λ, or the wiring length corresponding to a specific band.

Accordingly, a meander pattern can be formed for each wiring layer using parameters appropriate for that wiring layer. Therefore, for example, noise corresponding to the specific band can be suppressed.

For example, the meander pattern may be included to give the wiring a length that is not a specific wiring length corresponding to a specific frequency band. Here, the specific wiring length is, for example, a wiring length that becomes an antenna pattern for a specific frequency band (specific band).

This prevents the wiring from becoming a specific wiring length corresponding to the specific band, and thus noise corresponding to the specific band can be suppressed.

For example, different specific wiring lengths may be set for the different wiring layers. Accordingly, the length of the wiring corresponding to a specific band can be calculated for each wiring layer, using parameters appropriate for that wiring layer. Therefore, noise corresponding to the specific band can be suppressed. For example, the different wiring layers may be a surface layer and an inner layer.

For example, the specific wiring length may be set based on the specific frequency band, a wiring width, and a thickness of an insulator prepreg. For example, the specific wiring length is calculated using (Equation 3) to (Equation 5) described above. Accordingly, the specific wiring length can be calculated with high accuracy by taking multiple parameters into account.

For example, electronic device 10 may be for in-vehicle use. For example, electronic device 10 may be an Electronic Control Unit (ECU) including at least one of an Active Sound Control (ASC) unit or an Active Noise Control (ANC) unit.

For example, a wiring method according to an aspect of the present disclosure is a wiring method for use in board 12 that includes a plurality of wiring layers in each of which wiring 31 (or wiring 32) is disposed, the wiring at least partially including meander pattern 33 (or meander pattern 34). The wiring method includes: setting the meander pattern based on different parameters for wiring disposed in different wiring layers among the plurality of wiring layers. Here, the parameters are, for example, the propagation velocity v, the wavelength λ, or the wiring length corresponding to a specific band.

Accordingly, a meander pattern can be formed for each wiring layer using parameters appropriate for that wiring layer. Therefore, for example, noise corresponding to the specific band can be suppressed.

### Other Embodiments

Although exemplary embodiments have been described above, the present disclosure is not limited to the foregoing embodiments.

For example, the electronic device according to the foregoing embodiments may be provided to a mobile device other than a vehicle. The mobile device may be, for example, an aircraft, or a ship. Furthermore, the present disclosure may be realized as such a mobile device other than a vehicle.

Furthermore, the general or specific aspects of the present disclosure may be implemented as a system, an apparatus, a method, an integrated circuit, a computer program, or a non-transitory computer-readable recording medium such as a CD-ROM. Furthermore, the general or specific aspects of the present disclosure may be implemented as any combination of a system, an apparatus, a method, an integrated circuit, a computer program, and a non-transitory computer-readable recording medium.

Aside from the above, forms obtained by making various modifications to respective embodiments which can be conceived by those skilled in the art or forms realized by any combination of structural elements and functions in the respective embodiments within the essence of the present disclosure are included in the present disclosure.

### Further Information About Technical Background to This Application

The disclosures of the following patent applications including specification, drawings, and claims are incorporated herein by reference in their entirety: Japanese Patent Application No. 2023-130094 filed on Aug. 9, 2023, and PCT International Patent Application No. PCT/JP2024/021897 filed on Jun. 17, 2024.

### INDUSTRIAL APPLICABILITY

An electronic device according to the present disclosure is useful as, for example, an in-vehicle electronic device.

1. An electronic device comprising:
a housing;
a board that is disposed inside the housing and on which a plurality of circuit elements are mounted; and
a shield case that is provided on the board and is made of metal, wherein
among the plurality of circuit elements, a circuit element requiring electromagnetic shielding is placed in a region of the board where the shield case is provided.

2. The electronic device according to claim 1, further comprising:
a plurality of shield clips that electrically connect the shield case to a ground pattern of the board, wherein
intervals of the plurality of shield clips are set based on a propagation characteristic of a noise in vacuum.

3. The electronic device according to claim 2, wherein
the intervals of the plurality of shield clips are smaller than a specific interval based on the propagation characteristic of the noise in vacuum and greater than 1/20 of a wavelength of the noise.

4. The electronic device according to claim 3, wherein
the specific interval is determined based on a wavelength λ determined based on λ=v/f, where:
f is a frequency of the noise; and
v is a propagation velocity in vacuum, and
the specific interval is λ/2 or λ/4.

5. The electronic device according to claim 3, wherein
when the frequency of the noise is 2.10 GHz, the specific interval is 71.4 mm,
when the frequency of the noise is 1.60 GHz, the specific interval is 93.7 mm, and
when the frequency of the noise is 1.56 GHz, the specific interval is 96.1 mm.

6. The electronic device according to claim 1, wherein
the circuit element requiring the electromagnetic shielding includes a power supply circuit and an overload protection circuit.

7. The electronic device according to claim 1, wherein
the housing is made of resin.

8. The electronic device according to claim 1, wherein
the board includes a plurality of wiring layers,
at least a portion of wiring disposed in the plurality of wiring layers includes a meander pattern, and
the meander pattern is set based on different parameters for wiring disposed in different wiring layers among the plurality of wiring layers.

9. The electronic device according to claim 8, wherein
the meander pattern is included to give the wiring a length that is not a specific wiring length corresponding to a specific frequency band.

10. The electronic device according to claim 9, wherein
different specific wiring lengths are set for the different wiring layers.

11. The electronic device according to claim 9, wherein
the specific wiring length is set based on the specific frequency band, a wiring width, and a thickness of an insulator prepreg.

12. The electronic device according to claim 1, wherein
the electronic device is for in-vehicle use.

13. The electronic device according to claim 12, wherein
the electronic device is an Electronic Control Unit (ECU) including at least one of an Active Sound Control (ASC) unit or an Active Noise Control (ANC) unit.
